(19) United States
(12) Patent Application Publication
(10) Pub. No.: US 2015/0041191 A1
(43) Pub. Date: Feb. 12, 2015

(54) PRINTED CIRCUIT BOARD AND PREPARATION METHOD THEREOF

(71) Applicants: PEKING UNIVERSITY FOUNDER GROUP CO., LTD., Beijing (CN); FOUNDER INFORMATION INDUSTRY HOLDINGS CO., LTD., Beijing (CN); ZHUHAI FOUNDER PCB DEVELOPMENT CO., LTD., Zhuhai City (CN); ZHUHAI FOUNDER TECH. HI-DENSITY ELECTRONIC CO., LT D., Zhuhai City (CN)

(72) Inventors: Feng LIU, Zhuhai City (CN); Xinxing HU, Zhuhai City (CN)

(73) Assignees: PEKING UNIVERSITY FOUNDER GROUP CO., LTD., Beijing (CN); FOUNDER INFORMATION INDUSTRY HOLDINGS CO., LTD., Beijing (CN); ZHUHAI FOUNDER PCB DEVELOPMENT CO., LTD., Zhuhai City (CN); ZHUHAI FOUNDER TECH. HI-DENSITY ELECTRONIC CO., LT D., Zhuhai City (CN)

(21) Appl. No.: 14/091,538

(22) Filed: Nov. 27, 2013

(30) Foreign Application Priority Data
Aug. 8, 2013 (CN) 2013-10344561.9

(51) Int. Cl. H05K 3/00; H05K 1/09

(52) U.S. Cl. CPC H05K 3/0094; H05K 1/09
USPC 174/257; 216/18

(57) ABSTRACT

A printed circuit board and a preparation method thereof. The preparation method includes: making a first through hole in a core board including a metal layer; filling copper into the first through hole; forming a circuit pattern of the metal layer of the core board through an alkaline etching process; successively laminating a dielectric layer and a first copper foil on one side of the core board; making a second through hole opposite to and communicated with the first through hole, in the first copper foil; filling copper into the second through hole; and forming a circuit pattern of the first copper foil. The method for preparing the printed circuit board provided in the present invention can effectively reduce the preparation cost of the printed circuit board, greatly increase the yield of a product and further improve the universality of application.

### FIELD OF THE INVENTION

The present invention relates generally to printed circuit, in particular to a printed circuit board and a preparation method thereof.

### BACKGROUND OF THE INVENTION

In the manufacturing process of a printed circuit board, advantages of a through hole copper-filling process are quite significant, not only can the thermal reliability of the printed circuit board be improved, but also the mechanical strength of the through hole can be increased. Nowadays, electronic chips are miniaturized and increasingly higher the power consumption is highly increased. The heat dissipation demands of aeronautic and military electronic products are increasingly stronger. In other aspects such as civil electronic equipment, high-end mobile phone power panels launched by Apple Inc, Samsung and the like integrate an embedded capacitor and resistor technology, small in size, high in power consumption and harsh requirement on heat dissipation. As a result, high thermal conductivity of copper filled in through holes is applied to ensure the functions of the electronic products. Therefore, the through hole copper-filling process is widely used in the manufacturing process of the printed circuit board.

As shown in FIG. 1, during the through hole copper-filling process in the existing method for preparing the printed circuit board, a special chemical liquid needs to be used so as to fill the through hole 4 with copper, which results that the production cost for manufacturing the printed circuit board is relatively high. The through hole copper-filling process can be implemented on printed circuit boards with a thickness-diameter ratio of at most 1.2:1, which limit the applying the through hole copper-filling process to printed circuit boards with a higher thickness-diameter ratio.

In addition, in the existing process for manufacturing the printed circuit board, the through hole copper-filling process can be replaced by a resin hole-plugging process or a silver paste hole-plugging process. The resin hole-plugging process includes the processes of baking, polishing and the like, which may reduce the dimensional stability of the printed circuit board, and then drop the product yield. Meanwhile, the process has limitation in application to the printed circuit board with a thickness of more than 0.3 mm. Alternatively, the silver paste hole-plugging process has the shortcomings of high production cost, high process complexity and limitation in application.

### SUMMARY OF THE INVENTION

The embodiments of the present invention provide a printed circuit board and a preparation method thereof, which may effectively reduce the manufacturing cost of the printed circuit board, greatly increase the yield of an electronic product and further improve the universality of application.

One aspect of the present invention provides a method for preparing a printed circuit board including:
making a first through hole in a core board including a metal layer;
filling copper into the first through hole;
forming a circuit pattern of the metal layer of the core board through an alkaline etching process;
successively laminating a dielectric layer and a first copper foil on one side of the core board;
making a second through hole opposite to and communicated with the first through hole, in the first copper foil;
filling copper into the second through hole; and
forming a circuit pattern of the first copper foil.

Another aspect of the present invention further provide a printed circuit board obtained through the above-mentioned method for preparing a printed circuit board.

In the technical solutions of the present invention, the first through hole and the second through hole opposite to and communicated with the first through hole are made and are filled with copper respectively, so that the hole copper in the first through hole and the hole copper in the second through hole are connected into a whole. Compared with the through hole copper-filling process for the printed circuit board in the prior art, the present invention can effectively reduce the manufacturing cost of the printed circuit board, greatly increase the yield of the product and further improve the universality of application.

### BRIEF DESCRIPTION OF THE DRAWINGS

FIG. 1 is a schematic diagram of a vertical section of an existing printed circuit board after a through hole is filled with copper;

FIG. 2 is a flow schematic diagram of an embodiment of a preparation method of the present invention;

FIG. 3 is a schematic diagram of a vertical section of a printed circuit board before a through hole is made in an embodiment of the preparation method of the present invention;

FIG. 4 is a schematic diagram of a vertical section of the printed circuit board after a first through hole is made in an embodiment of the preparation method of the present invention;

FIG. 5 is a schematic diagram of a vertical section of the printed circuit board after the first through hole is filled with copper in an embodiment of the preparation method of the present invention;

FIG. 6 is a schematic diagram of a vertical section of the printed circuit board after a printed circuit pattern is formed in an embodiment of the preparation method of the present invention;

FIG. 7 is a schematic diagram of a top view structure of a copper ring after the printed circuit pattern is formed in an embodiment of the preparation method of the present invention;

FIG. 8 is a schematic diagram of a vertical section structure of a printed circuit board in the process of laminating a first copper foil, a second copper foil and a dielectric layer in an embodiment of the preparation method of the present invention;

FIG. 9 is a schematic diagram of a vertical section of the printed circuit board after the first copper foil, the second copper foil and the dielectric layer are laminated in an embodiment of the preparation method of the present invention;

FIG. 10 is a schematic diagram of a vertical section of the printed circuit board after a second through hole and a third through hole are made in an embodiment of the preparation method of the present invention;

FIG. 11 is a schematic diagram of a vertical section of the printed circuit board after the second through hole and the third through hole are filled with copper in an embodiment of the preparation method of the present invention; and

FIG. 12 is a flow schematic diagram of a second embodiment of the preparation method of the present invention.

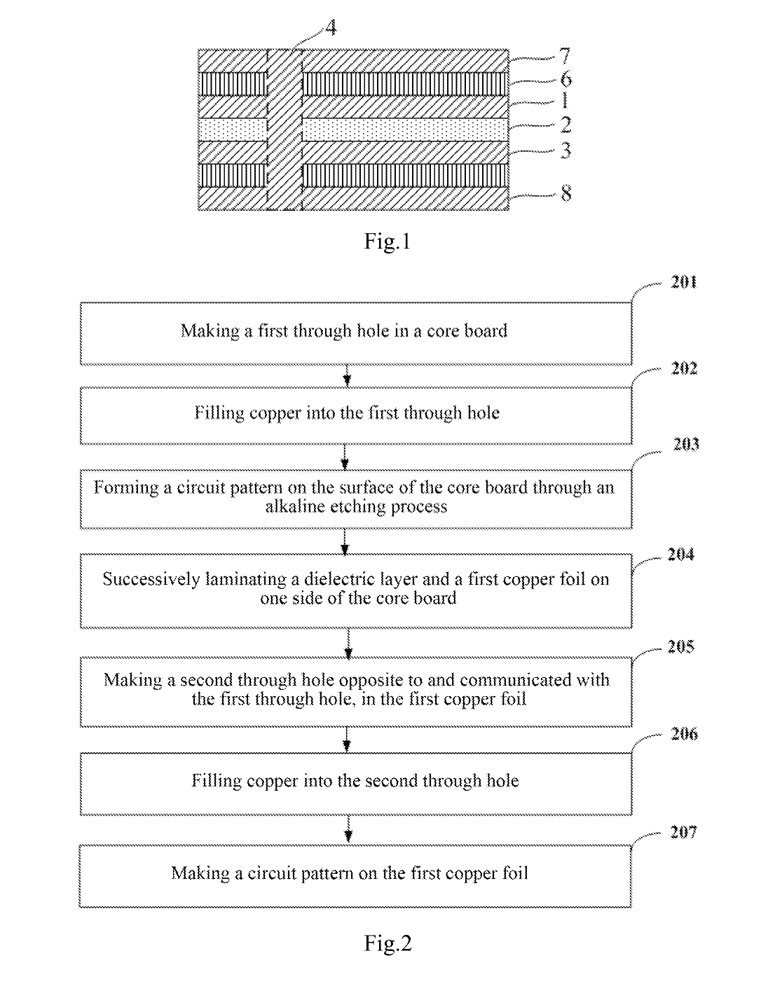

### SYMBOLS IN THE DRAWINGS

| | |
|---|---|
| 1-first copper board copper foil | 2-core board dielectric layer |
| 3-second copper board copper foil | 4-first through hole |
| 5-copper ring | 6-dielectric layer |
| 7-first copper foil | 8-second copper foil |
| 9-second through hole | 10-third through hole |

### DETAILED DESCRIPTION OF THE EMBODIMENTS

In Embodiments of the present invention, a printed circuit board and a preparation method thereof are provide, which can effectively reduce the manufacturing cost of the printed circuit board, greatly increase the yield of electronic product involving the printed circuit board and further improve the universality of application.

The provided method for preparing the printed circuit board is specifically described below through embodiments.

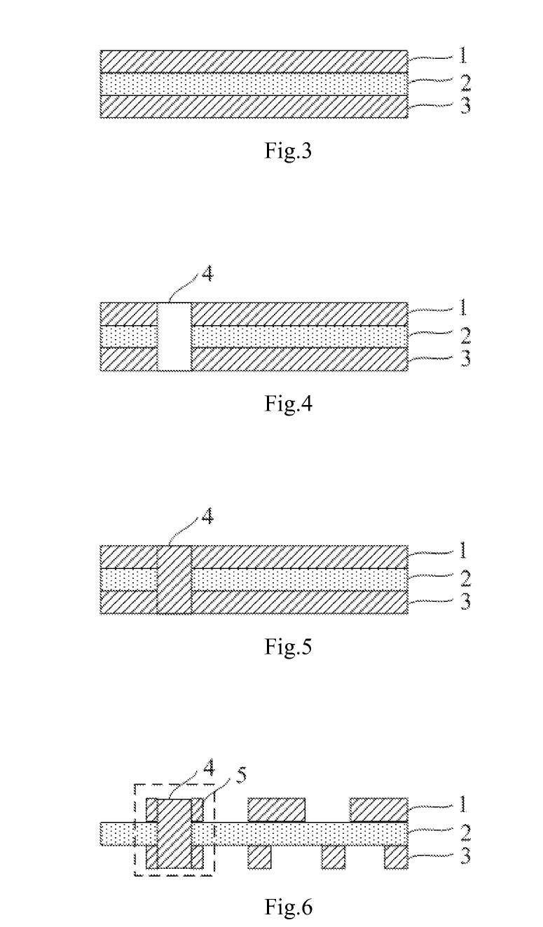

The preparation method provided in the embodiment shown in FIG. 2 includes:
step 201: as shown in FIGS. 3-4, making a first through hole 4 in a core board including a metal layer. The core board includes a first core board copper foil 1, a second core board copper foil 3 and a core board dielectric layer 2 located between the first core board copper foil 1 and the second core board copper foil 3, and the first core board copper foil 1 and the second core board copper foil 3 are both metal layers of the core board and both inner layers of the printed circuit board.

In step 201, laser drilling is more suitable for a hole with relatively small aperture due to limitation by a drill bit for mechanical drilling. When the diameter of the first through hole 4 is less than 0.125 mm (mainly in consideration of a drill bit, the present small drill bit with the diameter of 0.125 mm or 0.15 mm is relatively stable and economical), in making the first through hole 4, laser drilling is specifically adopted to make the first through hole 1. When the diameter of the first through hole 4 is more than 0.125 mm or 0.15 mm, in making the first through hole 4 in the core board, it is preferred to adopt mechanical drilling to make the first through hole 4, so that the shape of the hole would be better. In the manufacturing process of the printed circuit board, generally before using the laser, the laser drilling process specifically includes three steps: sticking a dry film; using a film and windowing the film; and etching a copper sheet at the corresponding position of making the through hole to expose a base material.

By adopting corresponding drilling methods for first through holes with different apertures, the aperture precision of the first through hole 4 can be effectively improved, and the yield of the product is further effectively increased.

Step 202: filling copper into the first through hole 4. The structure of the core board after step 202 is shown in FIG. 5.

Step 203: forming a circuit pattern of the metal layer of the core board through an alkaline etching process. The structure of the core board after step 203 is shown in FIG. 6.

In the manufacturing process of the printed circuit board, forming a pattern including the circuit through the etching process is specifically through alkaline etching process. The alkaline etching process includes: sticking a film onto the metal layer (usually the copper foil of the core board), exposing, developing, plating copper, plating tin, stripping the film, etching, stripping the tin, and finally forming the pattern.

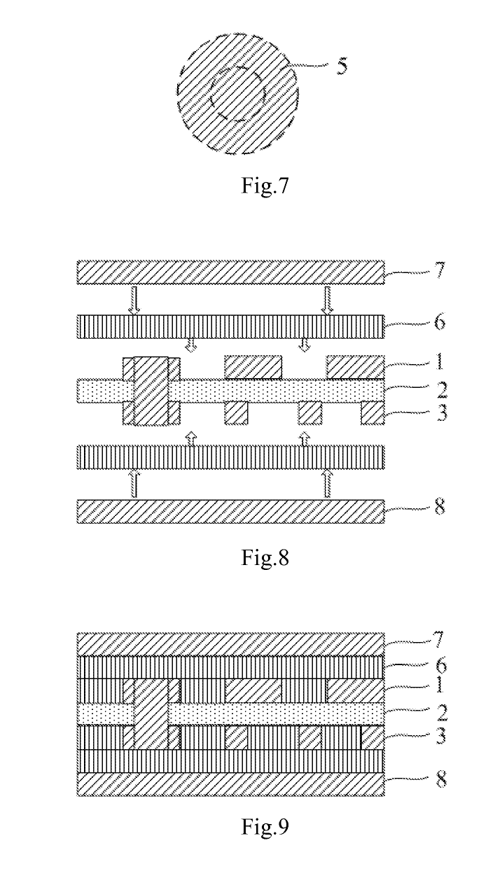

Preferably, in the embodiment shown in FIG. 7, in step 203, when forming the circuit pattern of the metal layer through the etching process, a copper ring 5 located at the first through hole 4 is also formed. The inner circle of the copper ring 5 coincides with the first through hole 4, and the outer circle of the copper ring 5 is more than the first through hole 4.

According to the practical experience, preferably, the outer circle diameter of the copper ring 5 is 0.1-0.15 mm more than the diameter of the first through hole 4. In this embodiment, preferably, the outer circle diameter of the copper ring 5 is 0.1 mm more than the diameter of the first through hole 4, which is not specifically limited herein. Because the inner circle of copper ring 5 is coincide with the first through hole 4 and the outer circle diameter of the copper ring 5 is a bit more than the diameter of the first through hole 4, the precision of a relative position between a second through hole made in the following process and the first through hole 4 can be effectively improved. After the second through hole is filled with copper, hole copper in the first through hole and hole copper in the second through hole can be connected smoothly to form a whole, so that the electrical property of the printed circuit board is effectively improved. As to the width of the copper ring (namely the part of diameter that the outer circle of the copper ring exceeds the first through hole), in comprehensive consideration of the actual capability of making the width of the copper ring, it is acceptable to achieve a balance between improving the alignment level and ensuring the surface wiring capability.

Preferably, in the embodiment of the preparation method provided in the present invention, the thickness of the core board is between 0.05 mm and 0.085 mm, which is favorable for fully filling the first through hole of the printed circuit board with the hole copper, and reduces the difficulty in forming the circuit pattern due to a too thin core board, thus effectively increasing the yield of the electronic product.

Step 204: as shown in FIG. 8, successively laminating a dielectric layer 6 and a first copper foil 7 on one side of the core board. The structure of the printed circuit board after step 204 is shown in FIG. 9.

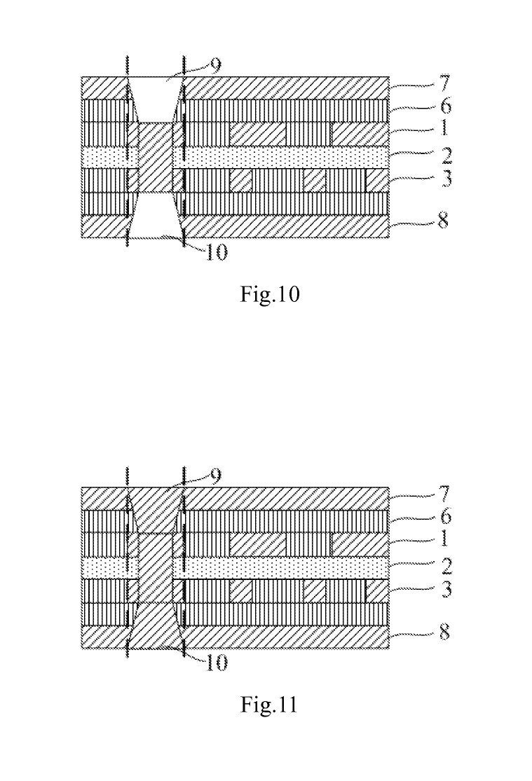

Step 205: making a second through hole 9 opposite to and communicated with the first through hole 4, in the first copper foil 7. The structure of the printed circuit board after the step 205 is completed is shown in FIG. 10.

In step 205, the making the second through hole 9 is specifically: making the second through hole 9 (the second through hole 9 is actually a blind hole herein, so it can be seen the longitudinal section of the second through hole 9 in FIG. 10 is trapezoidal) in a laser drilling mode, which is favorable for improving the drilling precision, so that the second through hole 9 and the first through hole 4 may be in better transition, and the yield of the product is further increased. The laser drilling step also includes the above-mentioned steps of windowing a dry film and etching a copper layer at the corresponding position.

When the first copper foil is a surface layer of the printed circuit board, a pad located at the second through hole is formed while forming the circuit pattern of the first copper foil in step 204, wherein the size of the pad is more than that of the second through hole. Under that circumstance, the pad functionally replaces the copper ring in the above-mentioned embodiment. The existence of the pad can effectively improve the precision of a relative position between the second through hole 9 and the first through hole 4.

Step 206: filling copper in the second through hole 9. The structure of the printed circuit board after step 206 is shown in FIG. 11.

In steps 202 and 206, the first through hole 4 and the second through hole 9 can be filled with copper by adopting a horizontal pulse plating copper-filling process.

In the embodiment provided by the present invention, when the first through hole 4 is filled with copper by adopting the horizontal pulse plating copper-filling process, plating parameters can be adjusted at any time with the filling condition of the hole copper in the first through hole 4, so that surface copper on the first core board copper foil 1 and the second core board copper foil 3 is effectively plated while the hole copper is plated, and the plating efficiency at the transition between the hole copper and the surface copper is improved., Thus, the uniformity and compactness of the hole copper in the first through hole 4 and facilitating the following preparation of the printed circuit board would be improved.

Step 207: forming a circuit pattern of the first copper foil 7.

In this embodiment provided by the present invention, the first through hole 4 and the second through hole 9 opposite to and communicated with the first through hole 4 are made and are filled with copper respectively, so that the hole copper in the first through hole 4 and the hole copper in the second through hole 9 are connected into a whole. Compared with the through hole copper-filling process for the printed circuit board in the prior art, through hole copper-filling of the printed circuit board with the thickness-diameter ratio can be achieved up to 1.9:1 in the embodiments of the present invention, and the hole copper in the filled through holes is void free and good in uniformity, so that the mechanical property and electrical property of the through holes of the printed circuit board are improved, the manufacturing cost of the printed circuit board is effectively reduced, the yield of the product is greatly increased, and the universality of application is further improved. Besides laminating the copper layer, drilling holes and filling the copper on single side of the core board as mentioned above, it is also possible to laminate copper layers, drill holes and fill the copper on double sides of the core board likewise, as long as adjustment is made according to design requirements.

The method for preparing the printed circuit board provided in the present invention is suitable for a printed circuit board with unlimited layers, such as a four-layer printed circuit board, an eight-layer printed circuit board and the like.

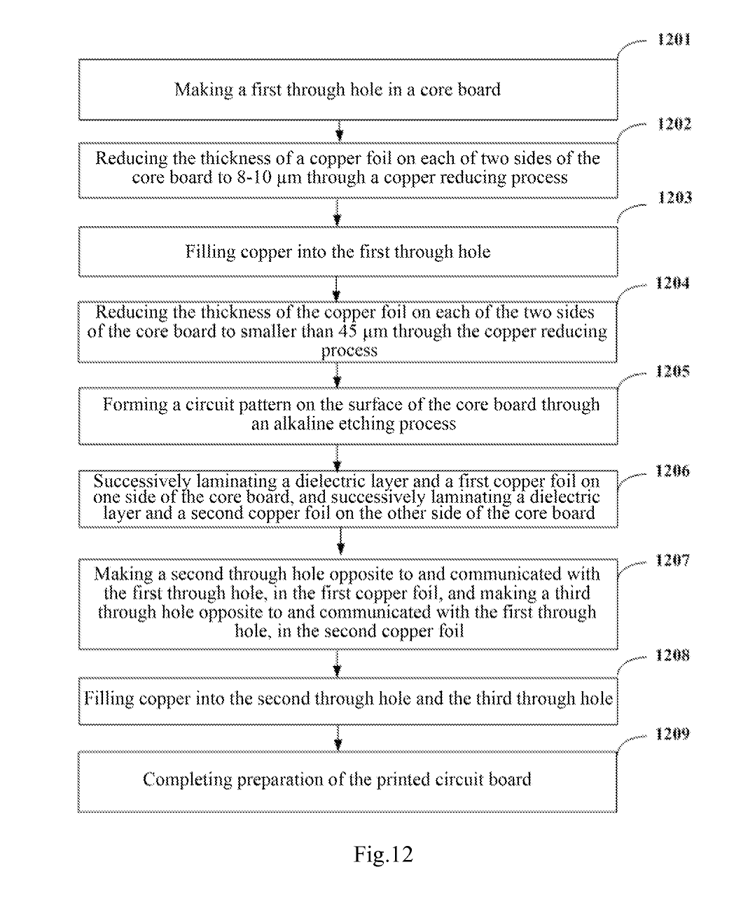

A method for preparing a printed circuit board provided in a second embodiment shown in FIG. 12, taking a four-layer printed circuit board as an example, includes:

step 1201: as shown in FIGS. 3-4, making a first through hole 4 in a core board including a copper foil on each side of the base material of the core board.

Step 1202: reducing the thickness of the copper foil of both sides of the core board to 8-10 μm through a copper reducing process.

In the process of forming a circuit pattern, the thicker the copper foil of the core board is, the lower the precision of forming circuit pattern is. Relatively, thin copper foils easily wrinkles, and the too thick and too thin copper foils are not favorable for production and processing of the printed circuit board. Generally, the initial thickness of the copper layer on both sides of the core board is about 10-35 μm, and the thick copper foil is thinned to 8-10 μm through a chemical copper reducing process, so that production and processing are easy to implement and the precision of printing the circuit on the printed circuit board is improved.

Step 1203: filling copper into the first through hole 4. The structure of the printed circuit board after step 1203 is shown in FIG. 5.

Step 1204: reducing the thickness of the core board copper foil on both sides of the core board to less than 45 μm through the copper reducing process. This step is added when the thickness of surface copper exceeds the value in the copper filling process of step 1203, and is intended for forming a finer circuit pattern in next step.

Step 1205: forming a circuit pattern of the metal layer of the core board through an alkaline etching process. The structure of the printed circuit board after step 1205 is shown in FIG. 6.

Step 1206: successively laminating a dielectric layer 6 and a first copper foil 7 on one side of the core board, and successively laminating a dielectric layer 6 and a second copper foil 8 on the other side of the core board. The structure of the printed circuit board after step 1206 is shown in FIG. 9.

Step 1207: making a second through hole 9 opposite to and communicated with the first through hole 4, through the first copper foil 7, and making a third through hole 10 opposite to and communicated with the first through hole 4, through the second copper foil 8. The structure of the printed circuit board after step 1207 is shown in FIG. 10.

Step 1208: filling copper into the second through hole 9 and the third through hole 10. The structure of the printed circuit board after step 1208 is shown in FIG. 11.

A pattern including a printed circuit is formed on both the first copper foil and the second copper foil through an etching process.

Step 1209: completing preparation of the printed circuit board.

The completing the preparation of the printed circuit board in step 1209 specifically includes mechanical rubbing, sticking of a dry film, exposure, development, etching, baking of the board, printing of a solder mask, printing of words, curing, forming, electrical testing, surface treatment and the like.

A method for preparing a printed circuit board provided in a third embodiment of the present invention, taking an eight-layer printed circuit board as an example, includes:
making a first through hole in a core board;
filling copper into the first through hole;
forming a circuit pattern of the metal layer of the core board through an etching process;
successively laminating a dielectric layer and a first copper foil on one side of the core board, and laminating a dielectric layer and a second copper foil on the other side of the core board successively or simultaneously;
making a second through hole opposite to and communicated with the first through hole, in the first copper foil, and making a third through hole opposite to and communicated with the first through hole, in the second copper foil;
filling copper into the second through hole and the third through hole;
forming a pattern including a printed circuit on both the first copper foil and the second copper foil through an etching process;
laminating a dielectric layer and a third copper foil on the first copper foil, and a dielectric layer and a fourth copper foil on the second copper foil;
making a fourth through hole opposite to and communicated with the second through hole, in the third copper foil, and making a fifth through hole opposite to and communicated with the third through hole, in the fourth copper foil; preferably, an X-ray drilling machine is used herein for performing laser drilling of the fourth through hole and the fifth through hole, with the first through hole as an alignment reference, and the alignment precision is improved compared with the case of the second or third through hole serving as the alignment reference;
filling copper into the fourth through hole and the fifth through hole;
forming a pattern including a printed circuit on both the third copper foil and the fourth copper foil through the etching process;
laminating a dielectric layer and a fifth copper foil on the third copper foil, and a dielectric layer and a sixth copper foil on the fourth copper foil;
making a sixth through hole opposite to and communicated with the fourth through hole, in the fifth copper foil, and making a seventh through hole opposite to and communicated with the fifth through hole, in the sixth copper foil; preferably, an X-ray drilling machine is used herein for performing laser drilling of the sixth through hole and the seventh through hole, with the first through hole as an alignment reference, and the alignment precision is improved compared with the case of the second or third through hole serving as the alignment reference;
filling copper into the sixth through hole and the seventh through hole;
forming a pattern including a printed circuit on each of the fifth copper foil and the sixth copper foil through the etching process; and completing preparation of the printed circuit board.

In this embodiment, preferably, when an inner circuit is made, the copper ring process (namely, reserving the copper at the edge of a through hole during etching) mentioned in preceding embodiments may also be adopted to make up the error of alignment; and when a surface circuit is made, a pad may be fabricated to replace the copper ring for implementation. Specific parameters are not described redundantly herein.

Besides laminating the copper layers, drilling holes and filling the copper on both sides of the core board as mentioned above, it is also possible to drill holes and fill the copper on single side of the core board likewise, as long as adjustment is made according to design requirements. In conclusion, the method for preparing the printed circuit board provided in the present invention effectively reduces the manufacturing cost of the printed circuit board, greatly increases the yield of the product and further improves the universality of application.

Based on the method for preparing the printed circuit board provided in the above-mentioned embodiments, the present invention also provides a printed circuit board, which is obtained through the preparation method of any of the above-mentioned embodiments.

Obviously, various modifications and variations may be made by those skilled in the art without departing from the conception and scope of the present invention. Thus the invention is also intended to encompass these modifications and variations thereto so long as these modifications and variations come into the scope of the claims of the invention and their equivalents.

What is claimed is:

1. A method for preparing a printed circuit board, comprising:
making a first through hole in a core board including a metal layer;
filling copper into the first through hole;
forming a circuit pattern of the metal layer of the core board through an alkaline etching process;
successively laminating a dielectric layer and a first copper foil on a side of the core board;
making a second through hole opposite to and communicated with the first through hole, in the first copper foil;
filling copper into the second through hole; and
forming a circuit pattern of the first copper foil.

2. The method according to claim 1, further comprising, before filling copper into the first through hole:
reducing thickness of the metal layer of the core board to 8-10 μm through a reducing process.

3. The method according to claim 1, further comprising, before forming the circuit pattern of the metal layer of the core board through the alkaline etching process:
if thickness of the metal layer of the core board is more than 45 μm, reducing the thickness of the metal layer of the core board to no more than 45 μm through a reducing process.

4. The method according to claim 1, wherein
when diameter of the first through hole is less than 0.125 mm, the first through hole is made in the core board by laser drilling;
when the diameter of the first through hole is more than or equal to 0.15 mm, the first through hole is made in the core board by mechanical drilling.

5. The method according to claim 1, wherein the second through hole is made by laser drilling.

6. The method according to claim 1, wherein thickness of the core board is between 0.05 mm and 0.085 mm.

7. The method according to claim 1, further comprising:
forming a copper ring located at the first through hole when forming the circuit pattern of the metal layer of the core board through said alkaline etching process, wherein outer circle of the copper ring is more than the first through hole.

8. The method according to claim 2, further comprising:
forming a copper ring located at the first through hole when forming the circuit pattern of the metal layer of the core board through said alkaline etching process, wherein outer circle of the copper ring is more than the first through hole.

9. The method according to claim 3, further comprising:
forming a copper ring located at the first through hole when forming the circuit pattern of the metal layer of the core board through said alkaline etching process, wherein outer circle of the copper ring is more than the first through hole.

10. The method according to claim 7, wherein the outer circle diameter of the copper ring is 0.1-0.15 mm more than the diameter of the first through hole.

11. The method according to claim 1, further comprising, when the first copper foil is a surface layer of the printed circuit board, forming a pad located at the second through hole while forming the circuit pattern of the first copper foil, wherein diameter of the pad is more than that of the second through hole.

12. A printed circuit board, obtained through the method according to claim 1.

13. A printed circuit board, obtained through the method according to claim 7.

14. A printed circuit board, obtained through the method according to claim 10.

15. A printed circuit board, obtained through the method according to claim 11.
